(19) United States
(12) Patent Application Publication
(10) Pub. No.: US 2008/0265869 A1
(43) Pub. Date: Oct. 30, 2008

(54) SWITCHING POWER SUPPLY PERFORMANCE TESTING

(76) Inventor: SAMUEL M. BABB, Fort Collins, CO (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/741,208

(22) Filed: Apr. 27, 2007

(51) Int. Cl. G01R 25/00; G01R 23/00

(52) U.S. Cl. 324/86

(57) ABSTRACT

One embodiment includes a system comprising a switching power supply comprising at least one switching phase configured to provide a corresponding phase output at a respective phase node thereof, the respective phase node being coupled to an output through a filter for providing a corresponding output signal. At least one resistor interconnects the respective phase node of each of the at least one switching phase with a test node, the test node being configured to provide a test signal representing the phase output at each phase node.

### BACKGROUND

There is an ever increasing demand for power conversion and regulation circuitry to operate with increased efficiency and reduced power to accommodate the continuous reduction in size of electronic portable devices. Switching power supplies control the flow of power to a load by controlling the on and off duty-cycle of a high-side switch coupled to the load via an inductor, and have thus been implemented as an efficient mechanism for providing a regulated output in power supplies. Some switching regulators include multiple stages (or phases) that can be activated in a time-division multiplexed manner, such that each stage provides power to the load at separate times. As performance demands of such power circuits continue to increase, so does the need to monitor such circuitry to ensure it operates within expected operating parameters.

### BRIEF DESCRIPTION OF THE DRAWINGS

FIG. 1 depicts an embodiment of a system for testing a switching power supply.

FIG. 2 depicts another embodiment of a system for testing a switching power supply.

FIG. 3 depicts a flow diagram depicting an example embodiment of a method for testing a switching power supply.

FIG. 4 depicts another flow diagram depicting an example embodiment of a method for testing a switching power supply.

### DETAILED DESCRIPTION

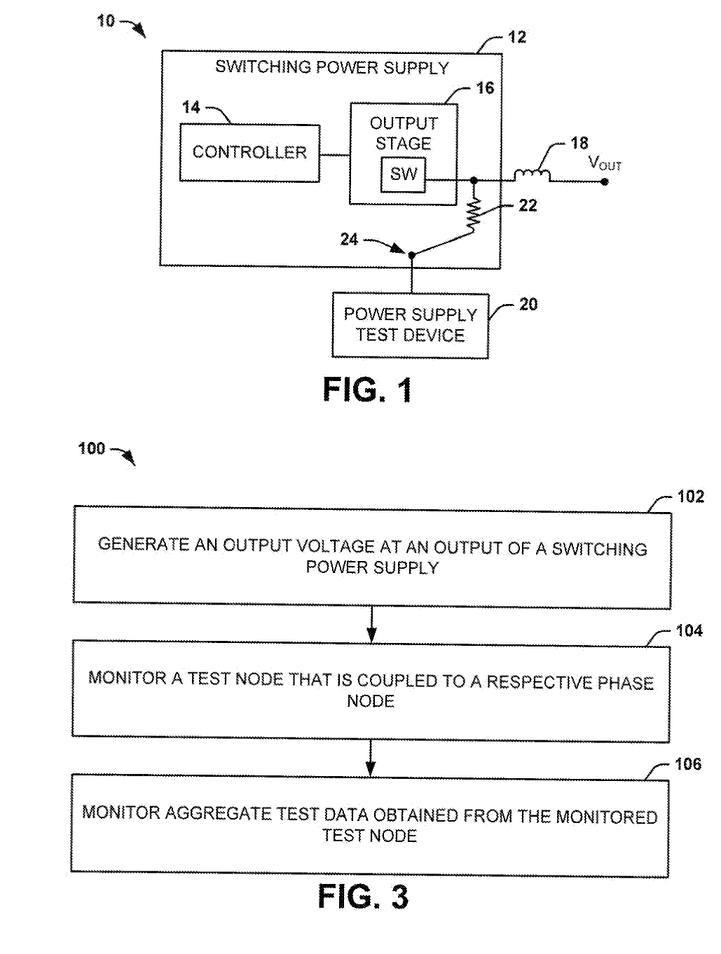

FIG. 1 depicts an embodiment of a system 10 for testing a switching power supply 12. The system 10 can be utilized subsequent to a manufacturing process of the switching power supply 12. For example, the system can be employed to test the switching power supply 12. Such tests can be performed to determine if the switching power supply 12 has been manufactured correctly and that the circuits operating according to predetermined specifications.

The switching power supply 12 includes a switching controller 14 and a power supply output stage 16. The output stage 16 can be configured as including one or more DC-DC converters. As one example, the output stage 16 can be implemented as a multi-phase interleaved synchronous Buck converter. Each phase (or stage) of the converter includes separate push-pull switching networks configured that collectively provide an output voltage, depicted at V_{OUT}. Each phase of the output stage thus can include a phase output node that is connected to V_{OUT} via one or more inductors 18. Although the example of FIG. 1 schematically demonstrates a single inductor 18, it is to be understood that the system 10 can include an inductor 18 for each of the respective phases of the output stage 16.

The switching controller 14 can be configured to control each of the phases of the output stage 16. For instance the switching controller 14 can include digital control circuitry that provides pulse-width-modulated output signals to associated driver circuits. The driver circuits provide control signals to operate devices in each of the switching phases of the output stage 16 individually. For instance the switching controller 14 can control each phase in a time-division multiplexed (TDM) manner.

In the example of FIG. 1, the switching power supply 12 can be implemented in one more integrated circuit (IC). For example, the switching controller 14 can be one IC and the output stage 16 can be implemented in another IC, which ICs can be implemented in a common module designed for use in a given application. The system 10 can be implemented to test the switching power supply 12 to ensure that the power supply stages have been manufactured according to design specifications. Additionally, the system can ensure that the power supply phases each operates within expected operating parameters. By way of example, the system 10 can utilized for testing during a final phase of production of the switching power supply 12. Alternatively or additionally, the system 10 can be implemented to troubleshoot the switching power supply 12 that has been previously configured in a power providing application in the event of suspected failure.

As an example, each phase of a multi-phase output stage 16 can include a high-side switch, such as a high-side field-effect transistor (FET) or an arrangement of FETs, which interconnects a positive supply voltage and a respective phase node. A low-side switch, such as a low-side FET or an arrangement of FETs is connected between the respective phase node and a low supply voltage, such as ground. The switching controller 14 can provide control signals to drive the high-side and low-side switches (e.g., in a pulse-width modulated manner) in accordance with the voltage and current requirements at the output. Stored energy in the inductor 18 can thus be released to maintain the current flow through the inductor 18. A capacitor (not shown) can also be placed in parallel with the load to reduce voltage ripple. Those skilled in the art will understand and appreciate other types and configurations of DC-DC converters that can be implemented at the output stage 16.

The switching controller 14 can subsequently activate a high-side switch in a different one of the phases of the output stage 16 to provide a current flow through another respective inductor 18. The controller 14 can selectively operate each phase of the output stage 16 independently (e.g., in a TDM manner) such that the output power supplied is distributed across the respective phases. Thus each phase of the output stage 16 aggregately contributes to the output voltage V_{OUT} based on the control signals output from the switching controller 14.

The system 10 also includes a power supply (PWS) test device 20. The power supply test device 20 can be configured to obtain operational data associated with the output stage 16. For instance, the power supply test device can monitor the operational data over a predetermined period of time, such as during typical operation of the switching power supply 12. One or more resistors 22 can electrically couple the output phase node to an output test node 24, such as can be coupled to a pin or terminal of the output stage 16. For example, the power supply test device 20 can be coupled to the pin 24 to monitor the operational data over the predetermined period of time while the switching power supply 12 provides the output voltage V_{OUT}. The operational data can include a summation of the signals (e.g., voltage and or current) associated with each of the phase nodes of each of the respective switching phases of the output stage 16.

While the system 10 is demonstrated in FIG. 1 as including a single resistor 22, the switching power supply 12 can be configured to include a resistor that interconnects each of the phase nodes with the test node 24. Such configuration enables the power supply test device 20 to ascertain aggregate operational characteristics of the phase nodes of the switching stages of the output stage 16 based on the summed signals monitored through each of the resistors. Because the switching of the respective phases of the output stage can occur at a very high-frequency, the operational data can likewise be provided to the power supply test device 20 as a high-frequency signal. As a result, the power supply test device 20 can be coupled to the switching power supply 12 with an appropriately impedance-matched connection. Thus, the resistor 22 in each phase of the output stage can be configured with appropriate resistance to maintain the impedance matching with the power supply test device 20. The information provided to the test node 24 provides unfiltered information (e.g., in contrast to the output V_{OUT}), from which a plurality of different operating parameters and characteristics for the output stage 16 and the switching power supply 12 can be determined by the power supply test device.

The power supply test device 20 can be further configured to calculate test data associated with the switching power supply 12 based on the operational data acquired from tire test node 24. As an example, the power supply test device 20 can employ the operational data to calculate a pulse rise-time and/or a pulse fall-time associated with the switching of the switching phases of the output stage 16. The power supply test device 20 can also calculate a period of the total switching waveform and/or a pulse width of the one or more high-side switch “on” times, as well as associated switching jitter characteristics. Furthermore, the power supply test device 20 can calculate data associated with voltage characteristics of the switching phases of the output stage 16, such as minimums and maximums of both the upper and lower voltage levels, as well as undershoot and/or overshoot characteristics. This test data can thus indicate whether the switching power supply 12 is operating correctly and/or according to specification, or whether the switching power supply 12 is a rejected part. More particularly, such an abundance of information enables a diagnosis of which component(s) may be defective and what particular defect may exist. As a result, more robust and precise switching power supply systems can be constructed based on information obtained by the power supply test system.

It is to be understood that the system 10 is not intended to be limited to the example of FIG. 1. Specifically, the system 10 is intended to provide a simplistic overview of the operation of the switching power supply 12, as well as an example of how the switching power supply 12 can be implemented and tested. It is therefore to be understood that the system 10 can be configured in any of a variety of ways.

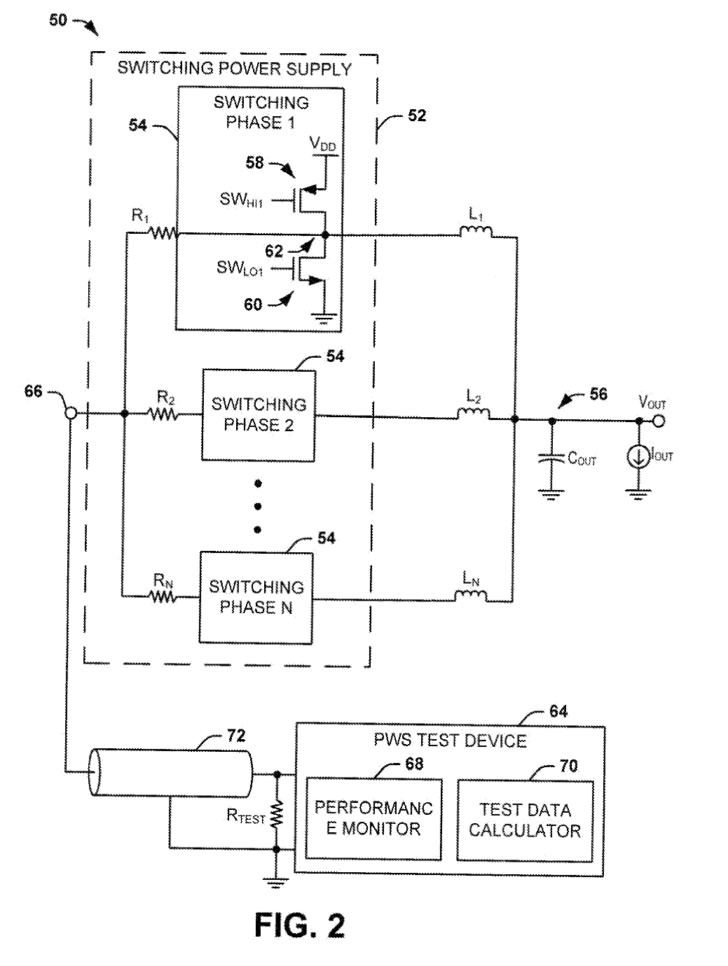

FIG. 2 depicts another embodiment of a system 50 for testing a switching power supply 52. Similar to as described above in the example of FIG. 1, the system 50 can be implemented subsequent to a manufacturing process of the switching power supply 52. As such, the test can be performed to determine if the switching power supply 52 has been manufactured correctly according to predetermined specifications. The switching power supply 52 can be implemented in one or more ICs. For example, the system 50 can be implemented to test the switching power supply 52 during a final phase of production of the switching power supply 52. Additionally or alternatively, the system 50 can he implemented to troubleshoot the switching power supply 52 that has been previously configured in a power providing application in the event of suspected failure.

The switching power supply 52 includes a plurality of switching, phases 54, demonstrated in the example of FIG. 2 as N switching phases, where N is a positive integer. Each of the switching phases 54 can be configured as a buck-converter switching stage, such as can be interleaved to provide an output voltage V_{OUT} at a node 56. In the example of FIG. 2, each phase node is connected to the output node 56 through a respective inductor L₁ through L_{N}. A capacitor C_{OUT} is connected across the output, such as to mitigate voltage ripple. The inductors and capacitor thus operate as a low pass filter to provide a desired filtered output V_{OUT}. A switching control circuit (not shown) can be configured to provide control signals to each of the switching phases 54 to operate each of the switching phases 54 individually in a TDM manner.

Switching Stage 1 is demonstrated in the example of FIG. 2 as having a high-side switch 58 and a low-side switch 60, demonstrated respectively as a P-type FET and an N-type FET. The high-side switch 58 interconnects a positive supply voltage V_{DD} and a phase node 62, and the low-side switch 60 interconnects the phase node 62 and a low supply voltage, demonstrated in the example of FIG. 2 as ground. It will be understood that the terms “low” and “high” as used with respect to voltages and to switching devices are utilized to indicate a relative associated voltage levels. The particular voltage levels can vary according to application requirements. The switching control circuit asserts a control signal SW_{HI1} to activate the high-side switch 58, such that the phase node 62 is coupled to the positive supply voltage V_{DD} through the high-side switch. Thus, a current flow is provided through the inductor L₁ to contribute to an output current I_{OUT} and to provide the output voltage V_{OUT}.

The switching control circuit subsequently deactivates the high-side switch 58 and asserts a control signal SW_{LO1} to activate the low-side switch 60, such that the phase node 62 is coupled to ground. Those skilled in the art will understand and appreciate various PWM schemes that can be utilized to provide corresponding DC output voltage V_{OUT} and corresponding current I_{OUT}. The filtering provided by the inductor L₁ and capacitor C_{OUT} operate to stabilize the voltage and current provided by the switching power supply 50. In this way, current continuously flows through the inductor L₁ to contribute to the output current I_{OUT}. Each of the remaining switching phases 54 similarly configured (e.g., the switching phases 54 can be identically configured circuits) to operate substantially the same. The switching control circuitry thus can provide control (e.g., PWM) signals to activate and deactivate respective high-side and low-side switches to provide desired output current and voltage. As described, herein the switching control circuit can operate the respective phases in a TDM (or interleaved) manner such that the power supply function is substantially evenly distributed across the N phases. Therefore, each of the switching phases 54 provides current flow through the respective inductors L₂ through L_{N} to aggregately contribute to the output current I_{OUT}, from which the output voltage V_{OUT} is provided at the node 56.

The system 50 also includes a power supply test device 64. The power supply test device 64 can be configured to be coupled to a test node 66 to determine test data associated with the switching phases 54. The lest node 66 can be configured as an external pin of an IC in which the switching power supply 52 is included, such that the power supply test device 64 can be configured to obtain the operational data, which can be subsequent to a final manufacturing phase. Therefore, the power supply test device 64 can determine the operating parameters while the switching power supply 52 provides die output voltage V_{OUT}. For example, the power supply test device 64 can compute the operating parameters, such as during a testing phase of production, to determine if the switching power supply 52 satisfies specification requirements and/or during a troubleshooting process to determine failure of one or more of the switching phases 54 of the switching power supply 52.

In the example of FIG. 2, the power supply test device 64 includes a performance monitor 68 and a test data calculator 70. The performance monitor 68 is configured to obtain operational data associated with the switching phases 54 over a predetermined period of time, such as during typical operation of the switching power supply 52. Thus, the operational data can be obtained while the switching power supply 52 provides the output voltage V_{OUT}. The operational data can include a high-frequency signal that is monitored at the test node 66 that is representative of the switching of the switching phases 54, as described below. Therefore, the performance monitor 68 can obtain an indication of the performance of the switching phases 54 during typical operation of the switching power supply 52. Such high-frequency switching information that is included in the operational data can thus be appropriately obtained from the test node 66, in contrast to V_{OUT} at the output node 56 due to the low-pass filtering characteristic of the inductors L₁ through L_{N}. In addition, the performance monitor 68 can include a digitizer configured to convert the operational data into a digital form.

In the example of FIG. 2, the switching power supply 52 includes a plurality of resistors R₁ through R_{N}, each being associated with a respective one of the switching phases 54. The resistor R₁ interconnects the phase node 62 and the test node 66, and the remaining resistors R₂ through R_{N} can likewise interconnect the test node 66 and the respective phase nodes of each of the remaining switching phases 54. The resistors R₁ through R_{N} can be integrated resistors that are configured as part of the IC in which the switching power supply 52 is included, such as N-well resistors. The operational data that is obtained by the performance monitor 68 can therefore include aggregate information provided at the test node 66, corresponding to a summation of signals associated with the phase nodes of the respective switching phases 54 through the resistors R₁ through R_{N}. As an example, the operational data can include high-frequency samples of at the test node 66 based on the TDM activation of the high-side and low-side switches in each of the respective switching phases 54. The summation of the signals at the test node 66 represents the signal characteristics for each of the phase nodes of the respective switching phases 54, thereby allowing high bandwidth measurements of all of the phase nodes 62 from one aggregated signal monitored at the test node. By way of further example, the performance monitoring at the test node 66 can be synchronized with the operation of each phase, such that signal characteristics and operating parameters associated with a given phase can be isolated relative to other phases.

Because the operational data that is obtained by the performance monitor 68 is a high-frequency signal, the power supply test device 64 may be coupled to the test node 66 with an appropriately impedance-matched connection. In the example of FIG. 2, the power supply test device 64 is demonstrated as coupled to the test node 66 via a test cable 72. The test cable 72 can be a balanced measuring cable having an impedance, for example, of approximately 50Ω. In addition, the performance monitor 68 may obtain the high-frequency operational data across a test resistor R_{TEST} that can be configured as having a resistance value of approximately 50Ω. Furthermore, the resistors R₁ through R_{N} can each have a resistance value that is approximately equal to N*R_{MATCH} (e.g., N*50Ω), where R_{MATCH} is the effective resistance at the node 66 (e.g., intended to match the resistance of the test cable 72) and where N being the number of switching phases 54. Therefore, the test cable 72 can be substantially impedance-matched with the test node 66. Accordingly, signal reflections between the test cable 72 and the test node 66 of the high-frequency operational data can be substantially mitigated. Those skilled in the art will understand and appreciate that the resistors R₁ through R_{N} could be set to other resistance value according to the resistance of the test cable 72 to mitigate reflections.

The test data calculator 70 is configured to calculate die test data associated with the switching power supply based on the operational data provided from the performance monitor 68. As an example, the test data calculator 70 can employ the operational data to calculate a pulse rise-time and/or a pulse fall-time associated with the switching of the switching phases 54. The test data calculator 70 can also calculate a period of the total switching waveform and/or a pulse width of the high-side switch “on” times, as well as associated switching jitter characteristics of the switching period and/or pulse width jitter. Furthermore, the test data calculator 70 can calculate data associated with voltage characteristics of the switching phases 54, such as minimums and maximums of both the upper and lower voltage levels, as well as undershoot and/or overshoot characteristics. This test data can thus indicate whether the switching power supply 52 is operating correctly and/or according to specification, or whether the switching power supply 52 is a rejected part.

It is to be understood that the system 50 is not intended to be limited to the example of FIG. 2. As an example, the switching power supply 52 is not limited to a single test node 66, but can include one test node for each of the phase nodes of the respective switching phases 54, or a given test node could be provided for a set of two or more selected phases. As a result, the current of each of the phase nodes of the respective switching phases 54 may permit the performance monitor 68 to obtain operational data associated with each of the switching phases 54 individually or in smaller sets of two or more phases. It is therefore to be understood that the system 50 can be configured in any of a variety of ways.

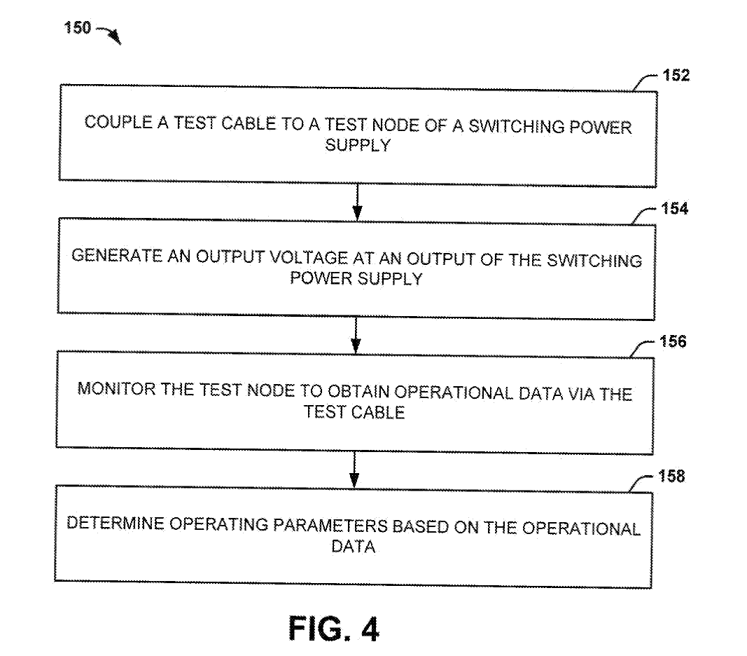

In view of the foregoing structural and functional features described above, certain methods will be better appreciated with reference to FIGS. 3 and 4. It is to be understood and appreciated that the illustrated actions, in other embodiments, may occur in different orders and/or concurrently with other actions. Moreover, not all illustrated features may be required to implement a method. It is to be further understood that the following methodologies can be implemented in hardware (e.g., a computer, a computer network or a specially designed test system), software (e.g., as executable instructions running on one or more computer systems or a specially design test, fixture), or any combination of hardware and software.

FIG. 3 depicts a flow diagram depicting an example embodiment of a method 100 for testing a switching power supply. At 102, an output voltage is generated at an output of a switching power supply. At 104, a test node that is coupled to a respective phase node interconnecting a high-side switch and a low-side switch of each of at least one switching phase is monitored. At 106, aggregate test data associated with the at least one switching phase is monitored based on operational data obtained from the monitored test node.

FIG. 4 depicts another flow diagram depicting an example embodiment of a method 150 for testing a switching power supply. At 152, a test cable is coupled to a test node of a switching power supply. The test node can be coupled to phase nodes of each of at least one switching phase of the switching power supply via impedance-matching resistors. The test cable can likewise be impedance-matched to the test node, such that signal reflections between the test cable and the test node can be substantially mitigated. At 154, an output voltage is generated at an output of the switching power supply. The switching supply can thus be operated in a typical fashion to provide the output voltage while the testing of the switching power supply is implemented.

At 156, the test node is monitored to obtain operational data via the test cable. The operational data can be obtained from a signal that is monitored at the test node. The high-frequency signal can be a summation of the signals at each of the phase nodes that is monitored over a predetermined period of time. The signals being monitored can correspond to voltage and/or current signals detected through the matched resistors. At 158, test data is calculated based on the operational data. The test data can corresponding to operating parameter, which may include at least one of pulse rise time, pulse fall time, switching period, switching period jitter, pulse width, pulse jitter, overshoot, undershoot, low level voltage, and high level voltage associated with the switching power supply. Those skilled in the art may understand other operating characteristics that can be determined based on the aggregate signals monitored at the test node. The test data can thus be indicative of whether the switching power supply meets predetermined specifications or is a rejected part.

What have been described above are examples of the present invention. It is, of course, not possible to describe every conceivable combination of components or methodologies for purposes of describing the present invention, but one of ordinary skill in the art will recognize that many further combinations and permutations of the present invention are possible. Accordingly, the present invention is intended to embrace all such alterations, modifications, and variations that fall within the spirit and scope of the appended claims.

What is claimed is:

1. A system comprising:
a switching power supply comprising at least one switching phase that configured to provide a corresponding phase output at a respective phase node thereof, the respective phase node being coupled to an output through a filter for providing a corresponding output signal; and
at least one resistor interconnecting the respective phase node of each of the at least one switching phase with a test node, the test node being configured to provide a test signal representing the phase output at each phase node.

2. The system of claim 1, further comprising a power supply test device coupled to the test node and configured to acquire test data corresponding to the test signal provided at the test node.

3. The system of claim 2, wherein the power supply test device further comprises:
a phase monitor configure to monitor operation of the switching power supply over a given time period and to obtain operational data associated with the switching power supply; and
a test data calculator configured to calculate operating parameters associated with the switching power supply based on the acquired operational data.

4. The system of claim 3, wherein the operating parameters comprises at least one of pulse rise time, pulse fall time, switching period, switching period jitter, pulse width, pulse jitter, overshoot, undershoot, low level voltage, and high level voltage.

5. The system of claim 2, wherein the power supply test device is coupled to the test node via a test cable having a known impedance, and wherein the at least one resistor is matched to the known impedance of the test cable, such that signal reflections at the test node are substantially mitigated.

6. The system of claim 1, wherein the at least one switching phase comprises a plurality N of switching phases, each of the plurality of N switching phases providing a corresponding phase output at a respective phase node thereof, where N is a positive integer, a respective resistor interconnecting each respective phase node of each of the plurality of N switching phases with the test node, such that an aggregate test signal is provided at the test node associated with operation of the plurality of N switching phases.

7. The system of claim 1, wherein each of the at least one switching phase comprises an inductor interconnecting the respective phase node of each of the at least one switching phase and an output of the switching power supply.

8. The system of claim 1, wherein the switching power supply and the at least one resistor are configured in an integrated circuit (IC).

9. A method comprising:
generating an output voltage at an output of a switching power supply, the switching power supply comprising at least one switching phase that provides a corresponding output at a phase node thereof;
monitoring an aggregate signal at a test node, the test node being coupled to the respective phase node of each of the at least one switching phase; and
calculating aggregate test data associated with the at least one switching phase based on operational data obtained from the monitored aggregate signal at the test node.

10. The method of claim 9, wherein monitoring the test node comprises monitoring operation of the switching power supply over a given time period to generate the operational data, such that the aggregate test data is representative of the operation of the switching power supply over the given time period.

11. The method of claim 9, wherein the at least one switching phase comprises N switching phases, where N is a positive integer greater than or equal to two, each of the N switching phases providing a phase output at a phase node that is connected with a common output, a respective one of N resistors connecting each phase node with the test node, and wherein monitoring the test node comprises summing signals acquired through the N resistors associated with the respective phase node of each of the N switching phases.

12. The method of claim 11, wherein each of the N respective resistors has a resistance value that is substantially equal to (N*R_{MATCH})Ω, where R_{MATCH} is the resistance of a cable interconnecting the test node with a test device configured to perform at least the monitoring of the test node.

13. The method of claim 9, wherein calculating aggregate test data comprises computing at least one of pulse rise time, pulse fall time, switching period, switching period jitter, pulse width, pulse jitter, overshoot undershoot, low level voltage, and high level voltage associated with the switching power supply based on the aggregate signal monitored at the test node.

14. The method of claim 9, wherein monitoring the test node comprises coupling a test cable to the test node, the test cable having a known impedance, and obtaining the operational data across at least one resistor, which is connected between the test node and the phase node of the at least one switching phase and is matched with the known impedance of the test cable, such that signal reflections at the test node are substantially mitigated.

15. The method of claim 9, wherein generating the output voltage at the output of the switching power supply comprises passing current through each of at least one inductor interconnecting the respective phase node of each of the at least one switching phase and the output of the switching power supply.

16. A system comprising:
plural switching means for providing a switched output signal at each of a respective plurality of phase nodes that are coupled to an output of a switching power supply;
means for providing an aggregate test signal based on summing the switched output signal at each of the respective plurality of phase nodes; and
means for obtaining test data associated with the respective plurality of phase nodes based on the aggregate test signal associated with each of the plurality of phase nodes.

17. The system of claim 16, wherein the means for obtaining the test data comprises;
means for monitoring operation of the switching power supply over a given time period to obtain operational data; and
means for calculating the test data based on the operational data.

18. The system of claim 16, further comprising means for substantially mitigating signal reflections between the means for obtaining the test data and a test node at which the current associated with each of the respective plurality of phase nodes is summed.

19. The system of claim 16, wherein the test data comprises aggregate test data associated with each of the respective plurality of phase nodes.

20. The system of claim 19, wherein the aggregate test data associated with each of the respective plurality of phase nodes comprises at least one of pulse rise time, pulse fall time, switching period, switching period jitter, pulse width, pulse jitter, overshoot, undershoot, low level voltage, and high level voltage.
